(19) United States
(12) Patent Application Publication
(10) Pub. No.: US 2010/0282284 A1
(43) Pub. Date: Nov. 11, 2010

(54) CRYSTALLINE PLATE, ORTHOGONAL BAR, COMPONENT FOR PRODUCING THERMOELECTRICAL MODULES AND A METHOD FOR PRODUCING A CRYSTALLINE PLATE

(76) Inventors: Vladimir Fedorovich Ponomarev, Moscow (RU); Denis Gennadievich Ryabinin, Moscow (RU)

Correspondence Address: LADAS & PARRY LLP, 26 WEST 61ST STREET, NEW YORK, NY, 10023, US

(21) Appl. No.: 12/810,968

(22) PCT Filed: Jun. 30, 2009
(86) PCT No.: PCT/RU09/00320

§ 371 Date: Jun. 28, 2010

(30) Foreign Application Priority Data
Jul. 18, 2008 (RU) 2008129392

(51) Int. Cl. H01L 35/12; B32B 15/00; H01L 21/02

(52) U.S. Cl. 136/200; 428/577; 438/54; 257/E21.002

(57) ABSTRACT

The invention relates to the thermoelectrical industry and can be used for producing thermoelectrical devices based on the Peltier and Seebeck effects. In particular, the invention relates to a crystalline plate made of thermoelectric laminated material, to a component which is used for producing n- and p-type conductivity legs. The invention is also related to a method of manufacture of crystalline plates of a thermoelectric layered material based on the A^{V}B^{VI} solid solutions by using a directional crystallization process.

### BACKGROUND OF THE INVENTION

The invention is related to the thermoelectric instrument making industry and can be used for producing of thermoelectric devices based on the Peltier and Seebeck effects. In particular, the invention relates to a crystalline plate made of a thermoelectric layered material, an orthogonal bar and a component for producing legs of the n- and p-type of conductivity in manufacture of thermoelectric modules. Besides, the invention is also related to the method for producing crystalline plates of a thermoelectric layered material based on A^{V}B^{VI} solid solutions by using a directional crystallization technique, particularly, the Bridgman method.

A thermoelectric module consists of semiconductor legs of p- and n-type of conductivity fabricated of crystals based on the A^{V}B^{VI} solid solutions and placed between two dielectric substrates, their surfaces featuring switching pads connecting the semiconductor legs into a single electric circuit. There is a wide range of materials, which can be used for direct conversion of temperature gradient into electric current, and vice versa. Materials based on solid solutions of bismuth telluride have been long standard materials for manufacture of legs of thermoelectric modules, due to their high value of thermoelectric efficiency Z. However, as the required properties of the A^{V}B^{VI} materials, both thermoelectric and mechanical ones, are structure-sensitive, i.e. pre-determined by the crystalline structure of materials, and at the same time have a layered structure with a pronounced orientation of cleavage planes, obtaining high thermoelectric parameters of devices concurrently with retaining the desired mechanical strength of articles it requires orientating the material cleavage planes in the finished product in a strictly defined way (see, e.g., patents, U.S. Pat. No. 5,950,067; U.S. Pat. No. 6,815,244; U.S. Pat. No. 6,114,052). Availability of pronounced cleavage of the A^{V}B^{VI} materials, i.e., their ability to cleave along particular crystal planes, in directions, where the chemical bonds of the lattice are weakened, determines the layered structure of thermoelectric material, and hence, the problem of cutting the material into components suitable for use as legs of thermoelectric modules. Therefore, creating thermoelectric devices, the operation of which is based on the Peltier and Seebeck effects, involves imposing requirements, both to obtaining high thermoelectric parameters of devices, and to retaining the mechanical strength of the material of legs in the course of repeated thermocycling of the devices.

Patent RU, 2160484 discloses a cast plate of a thermoelectric layered material and technology of fabricating the aforesaid plate by the casting method. A cast plate of the A^{V}B^{VI} material has parallel opposite faces and features a layered structure forming at least two matrices of cleavage planes mutually misaligned in such a way that the cleavage planes of the first matrix are inclined both to the cleavage planes of the second matrix and to the base surfaces of the plate. The fact that the structure of the plate material obtained by the casting method has at least two misaligned matrices of cleavage planes causes problems in cutting the plates into rectangular bars, as there is uncertainty in determination of orientation of the cutting plane, in respect of both at least two cleavage matrices and the base surfaces of the plate.

Patent RU, 2181516 and published international application WO/KR2002/021606 disclose the design of a semiconductor article for thermoelectric devices having parallel contact surfaces and a leg comprising at least two parts differing in composition and the value of the Seebeck factor. In advance, through the directed crystallization technique, ingot plates are grown based on solid solutions of bismuth telluride, whereupon the ingot plates are cut into parts in a direction normal to their base surfaces. Such implementation of parts of the article makes it possible to improve the parameters of devices owing to the fact that, apart from thermoelectric parameters of parts of the article, there emerge two more geometrical parameters of parametric control, namely, the width and the height, which enable to additionally optimize the design of the article legs. The known device has a high mechanical strength ensured; however, there is a considerable mutual misalignment of cleavage planes in the substrate material due to limited possibilities for control of orientation of cleavage planes in the process of growing the ingot plate by the directed crystallization technique, which results in reduced mechanical strength of device, as well as the problems of cutting and improving the electrophysical characteristics.

There is a known implementation of legs of thermoelectric devices as composite ones, i.e., comprising two or more parts of different thermoelectric characteristics (see, e.g., L. I. Anatyrchuk. Thermocouples and thermoelectric devices. Reference book. Kiev, Naukova dumka, 1979, pp. 155-156). Efficiency of known devices, which are made of composite legs and must be orientated in a pre-determined way in the course of assembling, grows considerably, compared to the legs uniform in their properties. However, manufacture of devices with composite legs involves a number of problems related to the technology of connecting the parts constituting the legs, while preserving the required thermoelectric parameters and mechanical strength of the constituent legs, as well as related to subsequent assembling of thermoelectric modules consisting of a number of smaller legs.

### SUMMARY OF THE INVENTION

Within the framework of this application, the problem is solved of developing such a method for obtaining a crystalline plate by the directional crystallization technique, which would allow obtaining a more perfect crystalline structure of the plate material with smaller angles of misalignment of cleavage planes owing to increased efficiency of control over the orientation of the cleavage planes, both at the stage of crystal nucleation, and in the process of growth. Besides, the problem is solved of retaining the mechanical strength of ingot plates in the process of repeated thermocycling of thermoelectric devices. The problem of improving thermoelectric parameters is also solved, with the prime cost of manufacturing the devices to be lower.

The solution of the set problem lies in the fact that a crystalline plate, the base surfaces of which are mutually parallel and have orientation {0001}, is grown with the help of the directed crystallization method of a thermoelectric layered material with a rhombohedral system of the n- or p-type conductivity, characterized by a number of crystal cleavage planes having virtually a single crystallographic direction, with formation of a texture with misalignment angle α≦6° and orientated virtually in parallel to the base surfaces of the crystalline plate, where the angle between the direction of the material's maximum thermoelectric efficiency and the direction of the ingot plate's maximum growth rate is virtually equal to zero. Besides, a crystalline plate thickness is a value within the range of 0.1-5 mm.

In practice, it is expedient to use solid solutions of the A^{V}B^{VI} materials of the n- or p-type conductivity, where Van der Waals forces act between the crystal cleavage planes, as a material for the ingot plate.

The solution of the set problem is also achieved by the fact that a orthogonal bar cut out of a stack of at least two aforesaid ingot plates has three couples of planes, one of which forms the opposite parallel planes with orientation {0001}, and the other two couples form, respectively, the opposite parallel longitudinal sides and the opposite lateral sides of the bar, where the opposite parallel longitudinal sides of the bar are planes of cutting the stack of ingot plates orientated normal to planes {0001}. Here, the angle between the direction of the maximum thermoelectric efficiency and the plane of cutting of the orthogonal bar, both in each ingot plate, and in the stack of ingot plates, makes an angle virtually equal to 90°.

Besides, on each of the opposite lateral sides of the bar, there is a layer of a solder binding crystalline plates in a stack, where a Sn—Bi alloy is used as the material of the solder binding the ingot plates in a stack.

The solution of the set problem is also achieved by the fact that a component for producing of thermoelectric modules cut out of the aforesaid crystalline plate has three couples of mutually perpendicular planes, one of which forms the opposite parallel planes with orientation {0001}, while the other two couples of planes form, respectively, the first couple of the opposite cutting planes with a metal coating applied on them, and the second couple of the opposite cutting planes normal to the first couple of cutting planes, where the angle between the direction of the maximum thermoelectric efficiency and the first couple of cutting planes with a layered metal coating applied on them, makes an angle virtually equal to 90°. It is preferable for the metal coating on the first couple of cutting planes to be made of materials taken from the following range: molybdenum, nickel, nickel-tin compounds, bismuth-antimony compounds, tin-bismuth compounds, or of a combination of the above metals.

The solution of the set problem is also achieved by the fact that the method of manufacture of crystalline plates by the directional crystallization method in the temperature gradient field comprising the steps of loading of a raw material into a container provided with a heater and installed above a matrix of vertically orientated graphite plates, each of which has an inlet channel and a cavity coupled in its lower part with a zigzag channel, subsequent heating of the raw material in the container up to the melting point accompanied by flowing of the melted material through the inlet channel to the cavity of the graphite plates, and creating a vertically orientated temperature gradient, where directed crystallization is performed at a rate not exceeding 0.5 mm/min by means of reducing the heater temperature.

Here, both the cavity, and the zigzag channel of each graphite plate, have a flat configuration and lie in the same plane, with the temperature gradient in the cavity of each profiled graphite plate created by locating the matrix of vertically orientated graphite plates on a cooled pedestal so that the zigzag channel of each graphite plate be located on the side of the cooled pedestal, and the inlet channel of each graphite plate be located on the side of the heater.

The essence of the invention is illustrated in the non-limiting example of embodiment thereof and the drawings attached thereto, where:

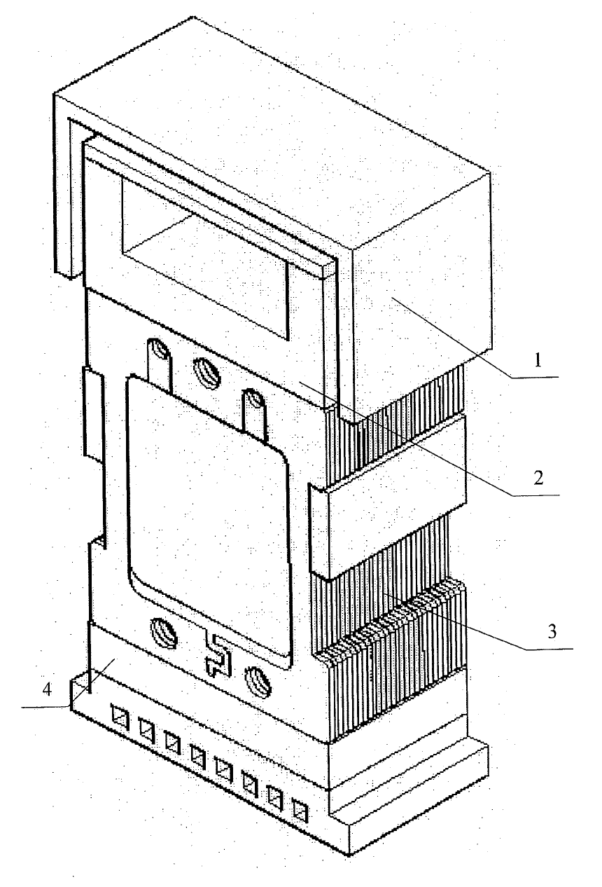

FIG. 1 is a general view of the thermal unit of a device intended for implementation of the claimed method for producing crystalline plates by the directional crystallization technique in the temperature gradient field.

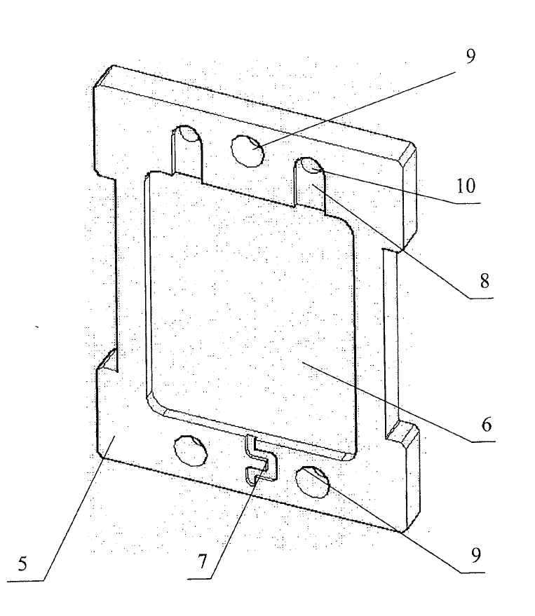

FIG. 2 is a general view of a graphite plate.

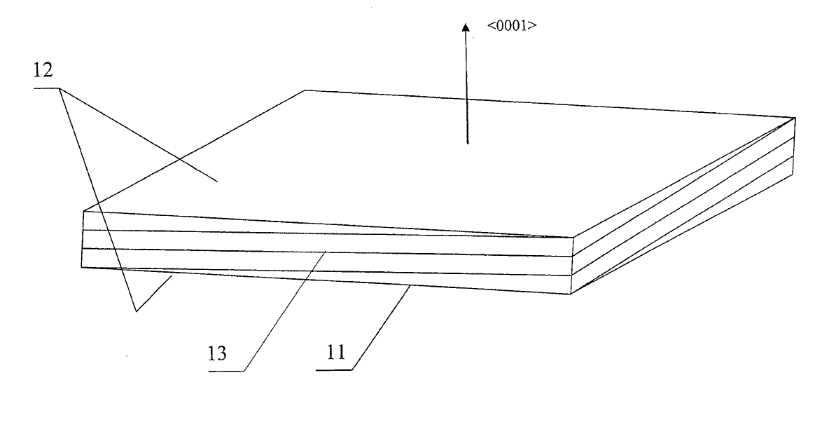

FIG. 3 is a general view of a crystalline plate of a thermoelectric material obtained by means of implementation of the claimed method and having crystal orientation of base planes {0001}.

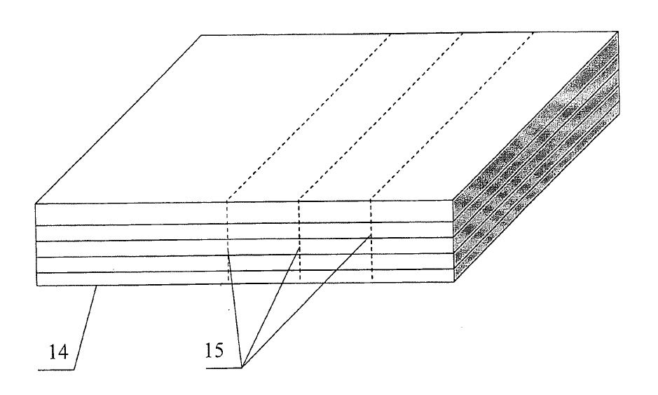

FIG. 4 is a general view of a stack of crystalline plates.

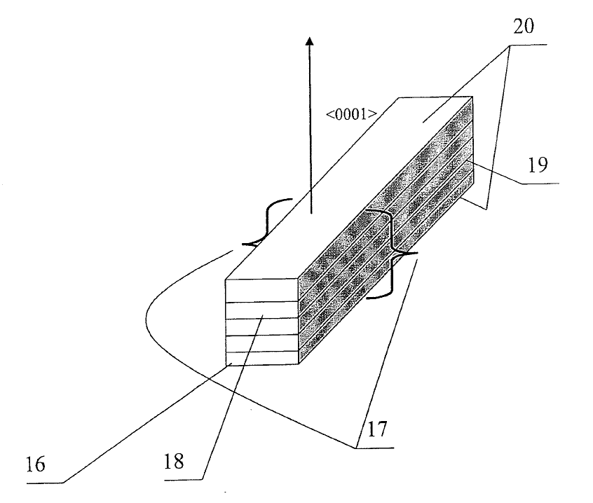

FIG. 5 is a general view of an orthogonal bar cut out of a stack of crystalline plates.

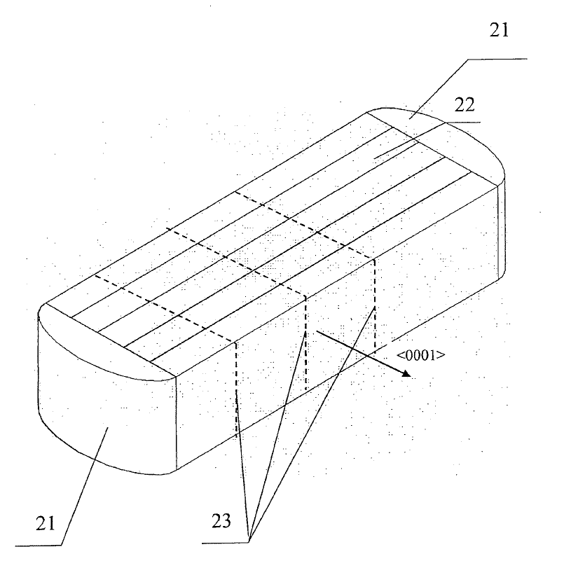

FIG. 6 is a general view of an orthogonal bar with a metal coating and a binding layer of solder.

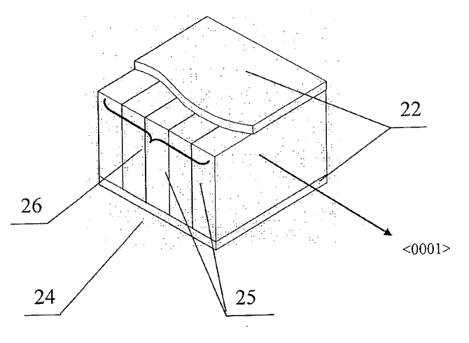

FIG. 7 is a general view of a component for producing thermoelectrical modules.

For explanation of the essence of the invention, the following keys are used in the drawings:

1—a heater; 2—a container; 3—matrix of vertically located graphite plates; 4—cooled pedestal; 5—a graphite plate; 6—a graphite plate cavity; 7—a zigzag channel; 8—a graphite plate inlet channel; 9—orifice for introduction of thermocouples; 10—orifice forming a channel in the matrix of graphite plates for the melt to flow; 11—a crystalline plate; 12—base planes of a plate with orientation {0001}; 13—layers of cleavage of a crystalline plate material; 14—stack of plates; 15—intersections of the first couple of cutting planes with the base planes and with the lateral planes of crystalline plates forming a stack; 16—an orthogonal bar; 17—first couple of cutting planes forming the opposite longitudinal sides of the bar; 18—opposite lateral sides of the orthogonal bar; 19—plate constituting the orthogonal bar; 20—opposite parallel sides of the bar with orientation {0001}; 21—layer of solder; 22—metal coating on the first couple of cutting planes; 23—cutting lines forming the second couple of cutting planes; 24—component; 25—plates constituting the electronic component; 26—second couple of cutting planes.

### DESCRIPTION OF THE PREFERRED EMBODIMENTS

Thin (0.25 mm) crystalline planes are grown from a pre-synthesized solid solution of bismuth telluride, e.g., Bi₂Te₃—Bi₂Se₃ and Sb₂Te₃—Bi₂Te₃ compounds, by the directed crystallization technique, namely, by the Bridgman method. Crystalline plates 11 (see FIG. 3) are fabricated by means of a plant, its thermal unit shown in FIG. 1, as follows.

A thermal unit designed for implementation of this method comprises heater 1 located in the upper part of the thermal unit, cooled pedestal 4 and a dismountable set of attachments consisting of container 2 for loading of the synthesized material and matrix 3 of graphite plates 5. Matrix 3 of graphite plates 5 is installed on cooled pedestal 4, and container 2 for loading of the synthesized material is installed above matrix 3 and connected with a piece (not shown in the drawing), which ensures flowing of the melt in the process of heating of the synthesized material from container 2 into cavity 6 of graphite plates 5.

Graphite plates 5 are installed vertically and arranged on pedestal 4 cooled in the process of directed crystallization. Graphite plates having cavities 6 (see FIG. 2) are installed closely to each other, with formation of the so-called cells for exercising directed crystallization of the solid solution of bismuth telluride in the temperature gradient field. Each of the graphite plates has orifice 10, inlet channel 8 and cavity 6 coupled with zigzag channel 7. Orifices 10 form in matrix 3 a channel for distribution of the melt among the so-called cells formed by planes 6 with graphite plates installed closely to each other. Cavity 6 and zigzag channel 7 of each graphite plate have a flat configuration and are located in the same plane. Inlet channel 8 made in the upper part of each graphite plate 5 and located opposite zigzag channel 7 is intended for distribution of the melted thermoelectric material of the n- or p-type conductivity. Controlled reduction of the temperature of heater 1 (see FIG. 1) at a rate of 50 deg/hr, combined with configuration of zigzag channel 7, ensure controlled orientation of the seeding material and controlled rate of growing a 0.25 mm thick plate, with obtaining a texture having misalignment angle of at most 5 degrees.

For performing the process of crystallization, container 2 is loaded with a pre-synthesized raw material—the solid solution of bismuth telluride and required additives in a pre-determined weight ratio. With the temperature of cooled pedestal 4 controlled, directed heat rejection from graphite planes 5 is exercised in the process of crystallization. The growth setup chamber (not shown) is vacuumized to the pressure of 10⁻² mm Hg, whereupon argon is introduced, and heating is switched on. Container 2 with a synthesized material is heated for 1 hour up to the temperature of 850° C. and exposed for 30 minutes at the above temperature for homogenization of the melt, whereupon container 2 is additionally heated up to the temperature of 950° C. Heating of the synthesized material in container 2 is accompanied with flowing of the melted material from container 2 into inlet channels 8 of graphite plates (see FIG. 2) and farther on, in cavities 6 and seeding channel 7 of graphite plates 5.

Then, the heater temperature is reduced. As the temperature is being reduced, the crystallization process spreads on channel 7 and the entire volume of cavity 6. The process of crystallization of the thermoelectric material is accompanied by formation of a series of 0.25 mm thick ingot plates in the cavity of the graphite plates.

The process of crystallization is performed at a rate for the material of the plate being crystallized to have a structure extending the structure of the material in seeding channel 7. The rate of crystallization, i.e., the maximum rate of shift of the crystallization front, is a value lying within the range of 0.1-0.2 mm/min.

As matrix itself 3 of graphite plates 5 is in the temperature gradient field created with heater 1 located in the upper part of the thermal unit and cooled pedestal 4 located in the lower part of the thermal unit, along with a decrease of the temperature in the lower part of zigzag channel 7, crystallization begins, where the crystallization front is gradually shifting upwards in cavity 6 of each graphite plate making a part of matrix 3. The lower part of zigzag channel 7 (see FIG. 2) is the closest to cooled pedestal 4, therefore, crystallization begins from the coldest part of seeding channel 6 coupled with cavity 6 of the graphite plate. All the sections of seeding channel 7 and cavity 6 of the graphite plates lie in the same plane. Along with a decrease in the temperature of cavity 6, there proceeds crystallization of the melt material at a certain rate determined by the value of the temperature gradient and the rate of decrease of the heater temperature. The material being crystallized gradually fills all the sections of seeding channel 7. As a result, by the moment, when the crystallization process moves from seeding channel 7 into cavity 6 of the graphite plate, a seeding crystal has been formed, its cleavage planes being in parallel to the plane of seeding channel 7 and, accordingly, to the plane of cavity 6 of the graphite plate.

The rate of the temperature decrease, combined with the temperature gradient, set the rate of the shift of crystallization front.

Owing to a considerable anisotropy of the rate of growth of materials based on bismuth telluride upwards along seeding channel 7, i.e., in the direction of the maximum crystallization rate, the fastest-growing are crystals, for which the direction of cleavage planes coincides with the direction of the maximum crystallization rate. Crystals with other orientation gradually degenerate. Further on, crystallization proceeds in a new direction, due to a turn of seeding channel 7. Crystallization proceeds in a direction normal to the primary direction. Though there is no temperature gradient in the perpendicular direction, crystallization and growth of crystals are going on in this direction. This is due to the fact that nucleation of new crystals requires a certain supercooling of the melt, while growth of already available crystals requires virtually no supercooling. Further on, each turn of seeding channel 7 and development of the crystallization process is accompanied by degeneration of crystals, whose cleavage planes are not parallel to the direction of the maximum crystallization rate.

As a result of directed crystallization in the temperature gradient field, with this device used for directed crystallization in the temperature gradient field, a series of 0.25 mm thick ingot plates is obtained in a single growth process, where the material of the ingot plates have a textured structure with a misalignment angle within 6°.

It will be appreciated that the seeding channel may as well be of a different shape; what matters, though, is for crystallization to be interrupted in mutually intersecting directions.

Obtained 0.25 mm thick crystalline plates 11 (see FIG. 3), in the amount of 5 pieces, are bound in a stack and then cut along first cutting planes 17 (see FIG. 5) orientated normal to the base surfaces of ingot plates having orientation {0001} (see FIG. 4), which results in having a series of orthogonal bars (see FIG. 5) bound at their butts, e.g., with a layer of solder 21 (see FIG. 6). The metal coating on the cut surface of the bound bars is common for all the bars and binds the bars on the side of the cut surfaces. The material serving for binding the bars in a stack is a BiSn solder. The binding material is a process material and is henceforth not comprised in the design of the leg. At the same time, the direction of the maximum thermoelectric efficiency in each bismuth telluride plate and in the stack coincide.

Components 24 (see FIG. 7) designed to be used as legs of thermocouples of the n- and p-type conductivity are cut along second cutting planes 26 (see FIG. 7) out of a bar consisting of 5 crystalline plates 11 of stratified bismuth telluride in such a way that, on the one hand, the layers are in parallel, and on the other hand, the angle between the direction of the maximum thermoelectric efficiency and the face with metal coating makes 90°. As a result, the direction of the current flow from one metal coating 22 second cutting planes 26 (see FIG. 7) to the opposite one (see FIG. 6,7) in working component 24 coincides with the direction of the maximum thermoelectric efficiency of the material of plates 25 (bismuth telluride) constituting component 24 (see FIG. 7).

For obtaining thermoelectric generator modules with pre-determined parameters, complex multi-layer metallized coatings are created on the surface of components of bismuth telluride. Based on requirements imposed for the modules, the composition of coatings is determined. It has been established that it is expedient to cover a prepared surface of the bismuth telluride element with an underlying layer of molybdenum having good anti-diffusion properties determined by low values of diffusion coefficients of the solder elements and copper, and a rather high adhesion to bismuth telluride. The anti-diffusion layer is required for increasing the heat resistance of the elements and extending the service life, which are reduced owing to degradation of properties caused by alloying bismuth telluride with the solder elements and copper. For the purposes of improving the conditions of wettability (“tinnability”) of the molybdenum coating, this is covered with a layer of nickel, which is “wetted” with tin, as well as with tin-based solders.

It will be appreciated that other types of the A^{V} B^{VI} thermoelectric materials can also be used in the process of fabricating ingot plates for manufacture of legs of thermoelectric devices by the method in question.

The invention can be used in manufacture of thermoelectric batteries (modules) of the direct (cooling/heating, thermal stabilization) and inverse (electric energy generation, registration of heat flows) energy conversion, which may be used as components for cooling devices, thermostatic control devices, climate systems, as well as other household and industrial purpose devices with a different final application. The invention provides for obtaining crystalline plates by the directed crystallization technique, which are characterized by the optimum structural and physical properties and enable to fabricate reliable thermocouples of a high thermoelectric efficiency and mechanical strength. This brings about a number of commercial advantages, including ability to obtain highly efficient thermoelectric cooling and generation modules of smaller geometrical dimensions, with their thermoelectric properties retained, which reduces the cost of thermoelectric devices.

1. A crystalline plate, its base surfaces being parallel and having orientation {0001}, grown through the directed crystallization method of a thermoelectric layered material with a rhombohedral system of the n- or p-type conductivity, characterized by a number of crystal cleavage planes having virtually a single crystallographic direction, with formation of a texture with misalignment angle α≦6° and orientated virtually in parallel to the base surfaces of the crystalline plate, where the angle between the direction of the material's maximum thermoelectric efficiency and the direction of the crystalline plate's maximum growth rate is virtually equal to zero.

2. The crystalline plate of claim 1, wherein its thickness is a value lying within the range of 0.1-5 mm.

3. The crystalline plate of claim 1, wherein solid solutions of the A^{V}B^{VI} materials of the n- or p-type conductivity are used as a thermoelectric material.

4. An orthogonal bar cut out of a stack of at least two crystalline plates of claim 1, wherein it has three couples of planes, one of which forms the opposite parallel planes with orientation {0001}, and the other two couples form, respectively, the opposite parallel longitudinal sides and the opposite lateral sides of the bar, where the opposite parallel longitudinal sides of the bar are planes of cutting the stack of ingot plates orientated normal to planes {0001}.

5. The orthogonal bar of claim 4, wherein the angle between the direction of the maximum thermoelectric efficiency and the plane of cutting of the orthogonal bar, both in each crystalline plate, and in the stack of crystalline plates, makes an angle virtually equal to 90°.

6. The orthogonal bar of claim 4, wherein on each of the opposite lateral sides of the bar, there is a layer of a solder binding the crystalline plates in a stack.

7. The orthogonal bar of claim 4, wherein a Sn—Bi alloy is used as a material of the solder binding the ingot plates in a stack.

8. A component for producing thermoelectric modules cut out of the orthogonal bar of claim 4, wherein it has three couples of mutually perpendicular planes, one of which forms the opposite parallel planes with orientation {0001}, while the other two couples of planes form, respectively, the first couple of the opposite cutting planes with a metal coating applied on them, and the second couple of the opposite cutting planes normal to the first couple of cutting planes, where the angle between the direction of the maximum thermoelectric efficiency and the first couple of cutting planes with a layered metal coating applied on them, makes an angle virtually equal to 90°.

9. The component of claim 8, wherein the metal coating on the first couple of cutting planes is made of materials taken from the following range: molybdenum, nickel, nickel-tin compounds, bismuth-antimony compounds, tin-bismuth compounds, or of a combination of the above metals.

10. A method for producing the crystalline plates of claim 1 by the directional crystallization technique in the temperature gradient field comprising the steps of loading of a raw material into a container provided with a heater and installed above a matrix of vertically orientated graphite plates, each of which has an inlet channel and a cavity coupled in its lower part with a zigzag channel, subsequent heating of the raw material in the container up to the melting point accompanied by flowing of the melted material through the inlet channel to the cavity of graphite plates, and creating a vertically orientated temperature gradient, where directed crystallization is performed at a rate within 0.5 mm/min by means of reducing the heater temperature.

11. The method of claim 10, wherein both the cavity and the zigzag channel of each graphite plate have a flat configuration and lie in the same plane.

12. The method of claim 10, wherein the temperature gradient in the cavity of each pro-filed graphite plate is created by locating the matrix of vertically orientated graphite plates on a cooled pedestal so that the zigzag channel of each graphite plate be located on the side of the cooled pedestal, and the inlet channel of each graphite plate be located on the side of the heater.

13. The orthogonal bar of claim 6, wherein a Sn—Bi alloy is used as a material of the solder binding the ingot plates in a stack.
